(19) United States
(12) Patent Application Publication
(10) Pub. No.: US 2025/0044329 A1
(43) Pub. Date: Feb. 6, 2025

(54) Systems and Methods for Monitoring and Analysis of Home Energy Use

(71) Applicant: STATE FARM MUTUAL AUTOMOBILE INSURANCE COMPANY, Bloomington, IL (US)

(72) Inventors: Christian Payne, Peoria, IL (US); Rick J. Campbell, Bloomington, IL (US); Mike Hambleton, Tempe, AZ (US); Tara Hayman, San Tan Valley, AZ (US); Jo-Jo Lin, Tempe, AZ (US); Zaki Goumandakoye, Dublin, CA (US); Diana Sherwood, Scottsdale, AZ (US); Joseph Harr, Bloomington, IL (US)

(21) Appl. No.: 18/601,488

(22) Filed: Mar. 11, 2024

Related U.S. Application Data
(60) Provisional application No. 63/530,513, filed on Aug. 3, 2023.

(51) Int. Cl. G01R 22/06; G06Q 50/06

(52) U.S. Cl. CPC G01R 22/06; G06Q 50/06

(57) ABSTRACT

Methods and systems for monitoring and analyzing electrical energy use at a site are disclosed herein. An electricity monitoring device configured to measure real-time electricity characteristics (e.g., instantaneous voltage levels) may be plugged into an outlet of an electrical circuit of a structure. The data obtained by such device may then be analyzed to determine electricity usage levels for the site and/or for individual electrical devices in the structure (e.g., based upon unique electrical signatures indicated by variations in voltage levels). The electricity usage levels may further be used to generate an energy use profile for the structure.

### CROSS-REFERENCE TO RELATED APPLICATIONS

This application claims priority to and the benefit of the filing date of provisional U.S. Patent Application No. 63/530,513 (filed Aug. 3, 2023), the entire contents of which are hereby expressly incorporated herein by reference.

### TECHNICAL FIELD

The present disclosure generally relates to energy monitoring and usage. More particularly, the present disclosure relates to monitoring and analyzing electrical power usage at a structure, such as a home.

### BACKGROUND

Electrical energy use at homes, businesses, and other structures may vary significantly both between similar structures and over time. While utility meters may provide overall energy use data over time, they may not distinguish between energy usage by different loads within the structures and also may not distinguish between energy usage at different times within a billing cycle (e.g., a month). Additionally, if an error occurs with a utility meter, the utility customer may be unaware of such error because of the difficulty of measuring electricity use for the entire structure. While plug-in devices to detect electrical faults (e.g., arcing current indicative of imminent fire risk) in home electrical wiring have been developed, such devices may not provide actionable information regarding safe but inefficient energy use by a home or by specific appliances therein.

Thus, existing systems may not appear to monitor and analyze electrical energy usage levels of a structure in order to provide useful information regarding reducing energy use in safe electrical systems. Conventional systems may include additional drawbacks, ineffectiveness, inefficiencies, and encumbrances as well.

### SUMMARY

The embodiments described herein generally relate to, inter alia, monitoring and analyzing electrical energy usage at a site. Such electrical energy usage monitoring may include measuring and analyzing electricity characteristics (e.g., real-time voltage fluctuations) at an electrical outlet of an electrical circuit within a structure, such as by an electricity monitoring device plugged into such an outlet. By monitoring the electricity characteristics over time by such a plug-in electricity monitoring device, energy usage levels and patterns of the structure may be determined without requiring disconnection of the circuit or rewiring to connect a monitoring device to an electrical distribution board (e.g., a fuse box or breaker box).

According to one aspect, a computer-implemented method for monitoring and analyzing electrical energy use of a structure may be provided. The method may be implemented via one or more local or remote processors, sensors, servers, transceivers, memory units, electricity monitoring devices, and/or other electric or electronic components, which may be in wired or wireless communication with one another. In one instance, the method may include: (i) monitoring or obtaining real-time electricity characteristics of an electrical circuit of the structure during a time interval by an electricity monitoring device plugged into an outlet of the electrical circuit, (ii) determining a plurality of electricity usage levels of the structure at a plurality of times within the time interval based upon the real-time electricity characteristics by one or more processors, and/or (iii) generating an energy use profile for the structure based upon the plurality of electricity usage levels by one or more processors, wherein the energy use profile includes one or more energy use scores for the structure. The real-time electricity characteristics may comprise variations in instantaneous voltage levels. In some embodiments, monitoring the real-time electricity characteristics may include establishing a communication connection with the electricity monitoring device and/or receiving the real-time electricity characteristics for the plurality of times within the time interval via the communication connection in one or more messages from the electricity monitoring device. The method may include additional, less, or alternate functionality, including that discussed elsewhere herein.

For instance, the plurality of electricity usage levels may comprise one or more appliance usage levels associated with respective one or more electrical appliances. Such electrical appliances may include a furnace, a water heater, a dishwasher, an oven, a washer, a dryer, and/or an electric vehicle charger. The one or more electrical appliances may be smart appliances configured to generate operating data regarding their operating status and/or condition. In some embodiments, one or more recommendations regarding adjustments to usage of the one or more electrical appliances may be generated based upon the one or more appliance usage levels. The recommendations may be presented to the user or homeowner in various manners, such as visually, graphically, or textually on a display or screen, such as via a mobile device, or verbally or audibly, such as via a voice bot, chatbot, or ChatGPT bot.

In further embodiments, operating data regarding operation of the one or more electrical appliances may be obtained by the electricity monitoring device, such as via wireless communication with the one or more electrical appliances. The plurality of electricity usage levels may be determined based in part upon the operating data. In yet further embodiments, an inventory of the one or more electrical appliances may be generated by identifying respective energy use signatures in the real-time electricity characteristics. The energy use profile may include one or more indications of conditions of the one or more electrical appliances relating to operating efficiency of the one or more electrical appliances, which conditions may be determined based upon the energy use signatures of the respective electrical appliances and/or operating data from the electrical appliances.

Some embodiments may include obtaining metered energy usage data regarding total electricity usage levels of one or more circuits at the structure, including the electrical circuit, by the electricity monitoring device via wireless communication with a smart meter disposed at the structure. The plurality of electricity usage levels may then be determined based in part upon the metered energy usage data.

Further embodiments may include the use of one or more trained machine learning models. For example, determining the plurality of electricity usage levels may include applying a trained machine learning model to the real-time electricity characteristics for the time interval to determine energy usage by a plurality of distinct electrical loads at the structure. As another example, generating the energy use profile may include applying a trained machine learning model to the plurality of electricity usage levels for the time interval to determine the one or more energy use scores. Some examples may further include (i) monitoring additional real-time electricity characteristics of the electrical circuit during an additional time interval by the electricity monitoring device, (ii) determining an additional plurality of electricity usage levels of the structure at an additional plurality of times within the additional time interval, (iii) generating an updated energy use profile for the structure based upon the additional plurality of electricity usage levels by applying the trained machine learning model to the additional plurality of electricity usage levels for the additional time interval to generate one or more updated energy use scores, (iv) determining a change between at least one of the one or more energy use scores and a corresponding at least one of the one or more updated energy use scores exceeds a change threshold level, and/or (v) causing a notification to be presented to a user of a user device indicating the change exceeding the change threshold level.

Systems or computer-readable media storing instructions for implementing all or part of the methods described above may also be provided in some aspects. Systems for implementing such methods may include one or more of the following: a client computing device associated with a user, a server associated with electrical energy use monitoring and analysis, one or more additional data sources, one or more electricity monitoring devices, one or more communication modules configured to communicate wirelessly via radio links, radio frequency links, and/or wireless communication channels, and/or one or more program memories coupled to one or more processors of any such computing devices or servers. Such program memories may store instructions to cause the one or more processors to implement part or all of the method described above. Additional, fewer, or alternative features described herein below may be included in some aspects.

### BRIEF DESCRIPTION OF THE DRAWINGS

The figures described below depict various aspects of the system and methods disclosed herein. It should be understood that each figure depicts an embodiment of a particular aspect of the disclosed system and methods, and that each of the figures is intended to accord with a possible embodiment thereof. Further, wherever possible, the following description refers to the reference numerals included in the following figures, in which features depicted in multiple figures are designated with consistent reference numerals.

FIG. 1 illustrates an exemplary computer system including an electricity monitoring device configured to monitor electrical energy usage.

FIG. 2 illustrates an exemplary environment in which an electricity monitoring device may be disposed to monitor electrical energy usage.

FIG. 3 illustrates an exemplary energy use monitoring method for detecting energy usage at a site and generating or updating an energy use profile associated with the site.

FIG. 4 illustrates an exemplary energy use analysis method that may be implemented by one or more processors to analyze electrical energy use at a site using machine learning techniques.

FIG. 5 illustrates an exemplary analytics server for analyzing electricity usage in accordance with certain aspects of the present disclosure.

### DETAILED DESCRIPTION

The present embodiments may relate to, inter alia, monitoring and analyzing electricity usage at a site, such as within an electrical system of a structure. In order to avoid installing a monitoring device within a supply line from an electrical power grid or within an electrical distribution board (e.g., a fuse box, breaker box, or breaker panel), an electricity monitoring device is configured to monitor real-time electricity characteristics (e.g., variations in voltage levels) of a circuit when plugged into an outlet of the circuit. Such real-time electricity characteristics are analyzed to determine one or more electricity usage levels for the structure, each of which indicate energy use for the structure as a whole or for individual circuits or devices within the structure. An energy use profile for the structure may further be generated to indicate electricity use.

### Exemplary System and Components

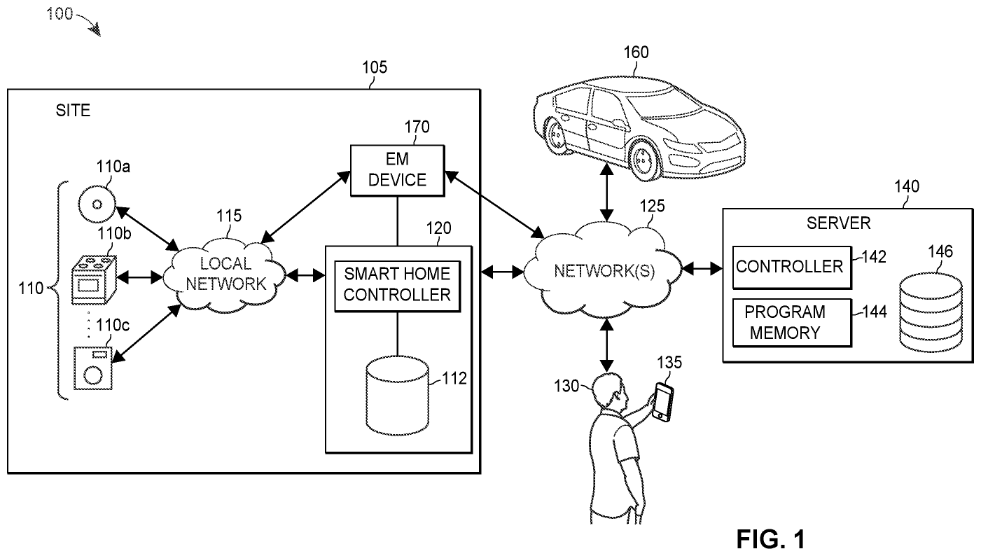

FIG. 1 depicts an exemplary system 100 including an electricity monitoring (EM) device 170 configured to monitor electrical energy usage. The EM device 170 may be configured to monitor real-time electricity characteristics by measuring variations in instantaneous voltage levels while plugged into an outlet of an electrical system of a structure (e.g., an electrical circuit of a home or business property). By measuring such changes in voltage levels over time, the load on the circuit and at the structure can be determined and used to generate an energy use profile for the structure. Although FIG. 1 depicts certain components and devices, it should be appreciated that additional, fewer, or alternate components or devices may be included in alternative embodiments.

As illustrated in FIG. 1, the system 100 may include a site 105, such as a building, which contains a smart home controller 120, a plurality of smart devices 110, and an EM device 170. Each of such components at the site 105 may be connected to a local network 115, enabling communication between the components or with external components, either directly or via one or more networks 125. Each of the plurality of smart devices 110 and/or the EM device 170 may be a “smart” device that may be configured with one or more sensors capable of sensing and communicating operating data associated with the local environment at the site 105 (e.g., energy usage by the smart device 110 or at the site 105).

As shown in FIG. 1, the plurality of smart devices 110 may include, as just a few examples, a smart meter 110a, a smart stove 110b, and a smart washing machine 110c. Each of the plurality of smart devices 110, as well as the EM device 170, may be located within or proximate to the site 105 (generally, “on premises” or “about the site 105”). Although FIG. 1 depicts only one site 105, it should be appreciated that multiple properties may be envisioned, each with its own components and connections. In some embodiments, the site 105 may be a single circuit within a building, such that each circuit may be separately monitored as a different site 105, in which case aggregated information regarding the building or portions thereof may be obtained by collecting and combining data from each of the relevant circuits.

Further, it should be appreciated that additional or fewer electrical devices may be present about the site 105, including other “smart” electrical devices and/or other conventional “dumb” electrical devices (i.e., non-communicating electrical devices). For example, other devices present at the site 105 may include a refrigerator, a microwave, a toaster, a television, a computer, telephone, a sound system, a light bulb or another lighting fixture, a washer, a dryer, an electrically-powered heating system, air conditioning system, water heater, and/or other suitable devices. Finally, it should be understood that, while the site 105 may be generally described herein as a home for convenience, the site 105 may be an office building, retail shop, industrial facility, or another suitable property or structure.

In some cases, the plurality of smart devices 110 may be configured by a manufacturer with the “smart” functionally incorporated therein. For example, a smart meter 110a may be installed at the site 105 to monitor and communicate energy use at the site (e.g., such as total electrical power used at the site), which may be monitored in a real-time or periodic manner. Thus, the EM device 170 or the server 140 may obtain metered energy usage data regarding total energy usage at the site 105 (or metered portion of the site) from the smart meter 110a, either directly or via a network 115 or 125. In other cases, the plurality of smart devices 110 may have been produced as “dumb” devices and subsequently modified to add the “smart” functionality to the device. For example, a homeowner may install an alarm system and connect a smart connection component to facilitate communication between such alarm system and the smart home controller 120.

Additionally, the plurality of smart devices 110 and/or the EM device 170 may be configured to communicate either directly or indirectly with smart home controller 120, such as via direct (wired or wireless) communication connections or via the local network 115. The local network 115 may facilitate any type of data communication between devices and controllers located on or proximate to the site 105 via any standard or technology (e.g., LAN, WLAN, any IEEE 802 standard including Ethernet, and/or others). The local network 115 may further support various short-range communication protocols such as Bluetooth®, Bluetooth® Low Energy, near field communication (NFC), radio-frequency identification (RFID), and/or other types of short-range protocols.

The plurality of smart devices 110, as well as the EM device 170, may transmit data generated, measured, or computed by the devices to the smart home controller 120 via the local network 115 and/or to a remote server 140 via a network 125. The data may include or be derived from data gathered from sensors associated with the plurality of smart devices 110, which may include environmental data measured by the devices (e.g., light, temperature, sound, air quality, or other environmental conditions in proximity to the devices) or operating data regarding operation of the devices (e.g., operating statistics, condition, or energy use of the devices). The environmental data may include audio data, image or video data, environmental status data (e.g., temperature, alarm sensor status, or data regarding other environmental conditions), and/or other data or information. The operating data may include operating status data, operating log data, energy usage data, operating condition or analysis data, or other data regarding the operation of a device.

The EM device 170 may collect environmental data regarding electricity characteristics observed at an outlet into which the EM device 170 is plugged, which may be indicative of electricity usage within the circuit connected to the outlet or at the site 105, generally. For example, the environmental data may include real-time voltage levels, such as variations in instantaneous voltage levels measured at the outlet by the EM device 170. In some embodiments, the EM device 170 may further collect operating data from one or more smart devices 110, either via direct (e.g., wireless) communication with such smart devices 110 or via communication with the smart home controller 120. The environmental and/or operating data collected by the EM device 170 may be analyzed by the EM device 170 to determine energy usage levels, or such data may be transmitted from the EM device 170 to a server 140 or other computing device for analysis. For example, energy usage levels may be determined by or based upon data collected by the EM device 170 for various appliances and other electrical devices, such as air conditioners, washers, dryers, dish washers, refrigerators, stoves, ovens, microwave ovens, televisions, lamps, outlets, computers, laptops, mobile devices, etc.

In some embodiments, the EM device 170 may detect electricity usage by one or more specific electronic device by identifying a unique electrical signature of each such device. The EM device 170 may thus determine electricity usage for various electronic devices within the home or connected to the site's electrical system. For example, a hybrid or fully electric vehicle 160 having its battery charged by the site's electrical system may be separately identified based upon an electrical signature indicating the charging.

The data collected by the EM device 170 may include a timestamp representing the time that the operating or environmental data was recorded. In some cases, the plurality of smart devices 110, as well as the EM device 170, may transmit various data and information to the smart home controller 120. In particular, the data and information may include location data within the property, as well as information collected by or regarding operation of the smart devices 110. For example, a washing machine may include data regarding times, extents, and settings of operation, which may directly or indirectly indicate energy usage levels.

The smart home controller 120 may be coupled to or include a database 112 that stores various environmental and/or operating data and information associated with the plurality of smart devices 110. Although FIG. 1 depicts the database 112 as coupled to the smart home controller 120, it is envisioned that the database 112 may be maintained in a “cloud” environment, such that any element of the system 100 capable of communicating over either the local network 115 or one or more other networks 125 may directly interact with the database 112. For example, a database 146 of a server 140 may be communicatively connected to the various components of the site 105 via the network 125. In some embodiments, the database 112 organizes the operational data according to which individual smart device 110 the data may be associated. Further, the database 112 may maintain an inventory list that may include the plurality of smart devices 110 as well as various data and information associated with the plurality of smart devices 110.

The smart home controller 120 or the EM device 170 may be configured to communicate with external devices, such as a server 140 via one or more networks 125. According to embodiments, the network 125 may facilitate any data communication between the smart home controller 120 or EM device 170 located on the site 105 and systems or devices remote to the site 105 via any standard or technology (e.g., GSM, CDMA, TDMA, WCDMA, 5G, LTE, EDGE, OFDM, GPRS, EV-DO, UWB, IEEE 802 including Ethernet, WiMAX, and/or others). In some cases, both the local network 115 and the network 125 may utilize the same technology or may be combined into one network.

The system 100 may include one or more servers 140 to receive and analyze data from the EM device 170 or the smart home controller 120 via the network 125. Each server 140 may include one or more computer processors within a controller 142 adapted and configured to execute various software applications and routines stored in a program memory 144 of the server 140, in addition to other software applications. The controller 142 may include or be connected to one or more processors (not shown), a random-access memory (RAM) (not shown), the program memory 144, and an input/output (I/O) circuit (not shown), all of which may be interconnected via an address/data bus (not shown). The RAM and program memory 144 may be implemented as semiconductor memories, magnetically readable memories, optically readable memories, or any other type of known or hereafter developed memory capable of storing executable instructions for execution by computer processors, such as the controller 142. The server 140 may further include one or more databases 146, which may be adapted to store data received from the EM device 170 or the smart home device 120, as well as data derived therefrom or other data relating to the site 105. Such data might include, for example, environmental data, operating data, energy usage levels, or energy use profiles associated with the site 105 or with other sites. The server 140 may access data stored in the database 146 when executing various functions and tasks associated with the system 100. Although referred to herein as a single database 146, multiple databases may be used in some embodiments, each of which may be relational or non-relational. The server 140 may further provide requested data to the other components (e.g., the smart home controller 120, the user device 135, or the EM device 170), such as energy usage levels, energy use profile data, or notifications regarding energy use.

The server 140, the smart home controller 120, or the EM device 170 may also communicate via the network 125 with an user device 135 (e.g., a smart phone or wearable computing device) associated with an user 130 (such as via wireless communication or data transmission over one or more radio links or communication channels). The user 130 may be an owner of the site 105 or a portion of the site 105, or may otherwise be associated with the site 105 (e.g., the user 130 may live in the site 105). The user device 135 may be a smartphone, a desktop computer, a laptop, a tablet, a phablet, a smart watch, smart glasses, smart contact lenses, wearable electronic device, or any other computing device.

The server 140, the smart home controller 120, or the EM device 170 may also communicate with a vehicle 160 associated with an user 130 or site 105 via the network 125 or the local network 115. The vehicle 160 may be an autonomous vehicle, semi-autonomous vehicle, smart vehicle, electric or hybrid vehicle, or other vehicle configured for wireless communication and data transmission over one or more radio links or communication channels. For example, the vehicle 160 may be an electric vehicle charging at the site 105.

### Exemplary System for Monitoring Electrical Activity

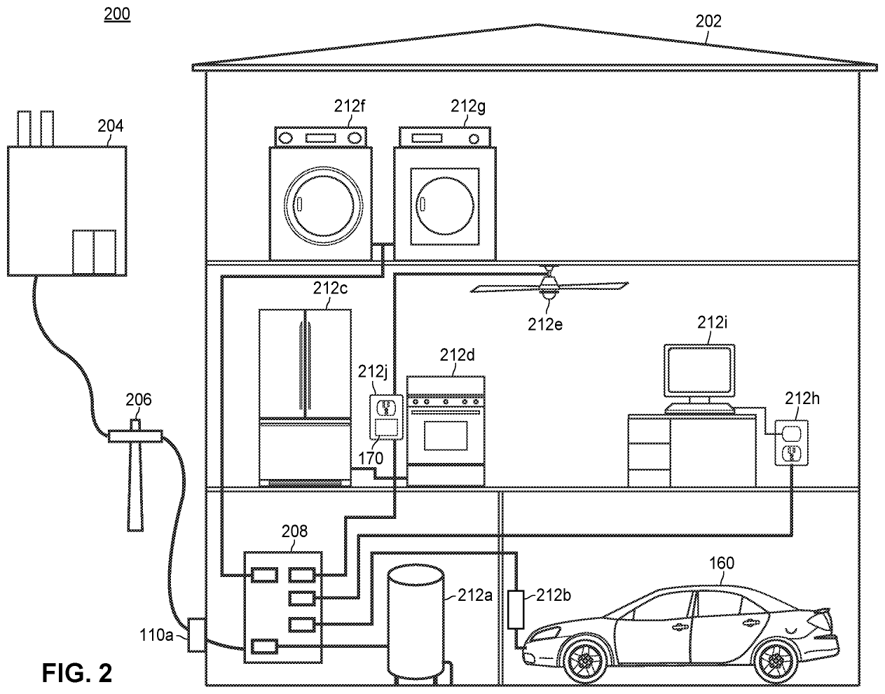

FIG. 2 illustrates an exemplary environment 200 in which the EM device 170 may monitor electrical energy usage of a structure 202. The environment 200 may comprise structure 202, such as a home having a plurality of electrical devices 212a-j, electrically powered through a plurality of circuits from an electrical distribution board 208. The electrical distribution board 208 in turn receives power from an electrical power grid 206, which is supplied by one or more power plants 204. Although structure 202 is depicted as a home having various appliances and other electrical devices 212a-j, it may be any other type of building or other site having at least one electrical circuit supplying power to other electrical devices (e.g., a structure housing offices and/or a business). Similarly, other configurations of additional, fewer, or alternative appliances 212 or other sources of electricity (e.g., another widespread electrical network, a local generator, a local solar panel array, or local or remote wind turbines) may be included in alternative embodiments. In alternative embodiments, the environment 200 may include additional, fewer, or alternate components, which may have additional, less, or alternative functionality, including that discussed elsewhere herein.

In any case, upon entering the structure 202, the electricity may be routed (e.g., via a hot wire) to an electrical distribution board 208 (also known and referred to as a “fuse box,” “breaker box,” or “breaker panel”) generally located within or about the structure 202. The electrical distribution board 208 may divide the received electricity between a plurality of electrical circuits, each of which in turn may transmit electricity to a respective one or more electrical devices within, around, or generally near or about the structure 202. In each of the plurality of circuits, a circuit breaker or fuse may protect against excess current at the circuit.

As depicted in FIG. 2, electricity may be transmitted via the electrical distribution board 208 to the electrical devices 212a-j at the structure 202. The electrical devices 212a-j may include a plurality of electrical appliances, such as an electric water heater 212a, an electric vehicle charger 212b for charging an electric vehicle 160, a refrigerator 212c, a stove 212d, a lighting fixture 212e, a washer 212f, and a dryer 212g. Further, devices about the structure 202 may include electrical outlets 212h and 212j, which may provide power to one or more electrical devices, such as a television 212i. As illustrated, an EM device 170 may be plugged into an electrical outlet, such as electrical outlet 212j. The electrical devices 212a-j are only exemplary, and it should be understood that other electrical devices (e.g., sensors, appliances, utility systems, electronics, etc.) may be among the electrical devices at the structure 202 receiving electricity via the electric distribution board 208. In some embodiments, other electrical devices may be connected to a smart meter 110a may be disposed between the electrical power grid 206 and the electrical distribution board 208, which may monitor and communicate meter data regarding total electricity usage levels for the structure 202.

In operation, as one or more of the electrical devices 212a-j receive electricity via the electrical distribution board 208, each device of the electrical devices 212a-j may be differentiated by an electrical signature that is unique to a respective device. In other words, transmission of electricity to the refrigerator 212c (and/or other electrical activity associated with the refrigerator 212c), for example, may be differentiated from transmission of electricity to the stove 212d. Furthermore, transmission of electricity to the television 212i via the electrical outlet 212h (and/or other electrical activity associated with the television 212i and/or outlet 212h), for example, may be differentiated from transmission of electricity to another recipient electrical device (e.g., a cable box) via the same electrical outlet 212h. Such electrical signatures may appear as characteristic variations in the voltage on the respective electrical circuit (or on all circuits connected to the electrical distribution board 208) associated with power drawn by the devices. For example, a compressor of the refrigerator 212c cause a characteristic voltage curve to appear over time when it starts, when it is running in steady state, and when it stops.

An EM device 170 may be connected to an electrical circuit by being plugged into an outlet 212j, which may be situated near the electrical distribution board 208. Generally, the EM device 170 may monitor real-time electricity characteristics of electricity at the circuit into which it is plugged, such as instantaneous voltages at the outlet 212j at various times. In some embodiments, the EM device 170 may detect the differentiable electrical signatures of the electrical devices 212a-j by monitoring such electricity characteristics of the circuit. The electricity characteristics of the circuit thus monitored by the EM device 170 at the outlet 212j may be analyzed to determine electricity usage levels on the circuit or at the structure 202, as discussed elsewhere herein. Thus, the EM device 170 may generate data streams or data sets including observed electricity characteristics, derived electricity usage levels, and/or received operating data, which data streams or data sets may include timestamps associated with such data.

Based upon the unique electrical signatures, the electricity usage levels may be correlated with respective electrical devices 212a-j. Further, electricity usage associated with other components of the site's electrical system (e.g., the electrical distribution board 208 or wiring about the structure 202) may be correlated with one or more electrical devices 212a-j to which the electrical activity also pertains. In some embodiments, the EM device 170 may perform the analysis and/or other functions described herein, via one or more processors of the EM device 170 that may execute instructions stored at one or more computer memories of the EM device 170. In other embodiments, the EM device 170 may monitor and record the electricity characteristics at the circuit into which it is plugged via the outlet 212j, and the analysis and/or other functions described herein may be performed at another system (e.g., a smart home controller 120 or a server 140), which may receive data and/or signals indicative of obtained data via one or more electronic messages or communications from the EM device 170. In any case, analysis of the electricity characteristics associated with the circuit and/or the respective electrical devices may produce data indicating, for example, the time, duration, and/or magnitude of electricity consumption by the electrical devices 212a-j during a period of electrical energy use monitoring.

Operating data regarding an electrical device 212a-j may include, for example, historical data indicating such electrical device's past operation patterns or trends. For example, historical data may indicate a time of day, day of the week, time of the month, etc., at which an electrical device 212a-j frequently uses electricity (e.g., a lighting fixture 212e may not use electricity on sunny afternoons or during late night hours of the day). As another example, historical data may include the total electricity consumption or usage rate of the electrical device 212a-j over a period of time. Additionally or alternative, historical data may include data indicating past events regarding the electrical device 212a-j (e.g., breakdowns, power losses, arc faults, etc.).

In some embodiments, the environment 200 may include one or more smart components. For example, a smart home controller 120 may be present about the structure 202, or any of the electrical devices 212a-j may be a smart device (e.g., a smart appliance or a smart outlet). The smart home controller 120 may further communicate with one or more sensors that may be located on or otherwise associated with electrical devices and/or other fixtures at the structure 202. Such sensors and smart devices may transmit to the smart home controller 120 data (e.g., usage data, error signals, telematics, etc.) that, alone or combined with the data obtained by the EM device 170, may produce further indication of electricity usage levels of the structure 202. The smart home controller 120 may be configured for wireless communication with each sensor and/or associated item interconnected with a smart home system or wireless network (e.g., the local network 115).

### Exemplary Methods for Monitoring and Analyzing Energy Use

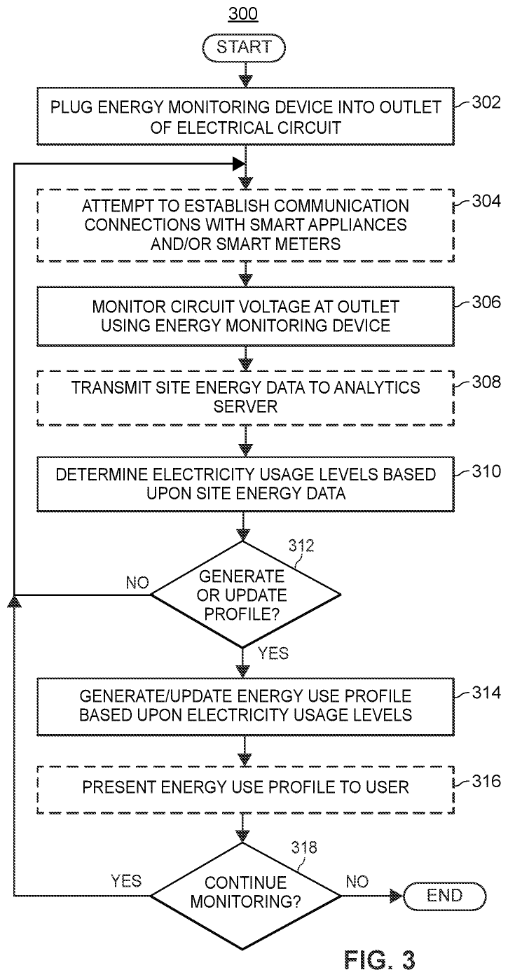

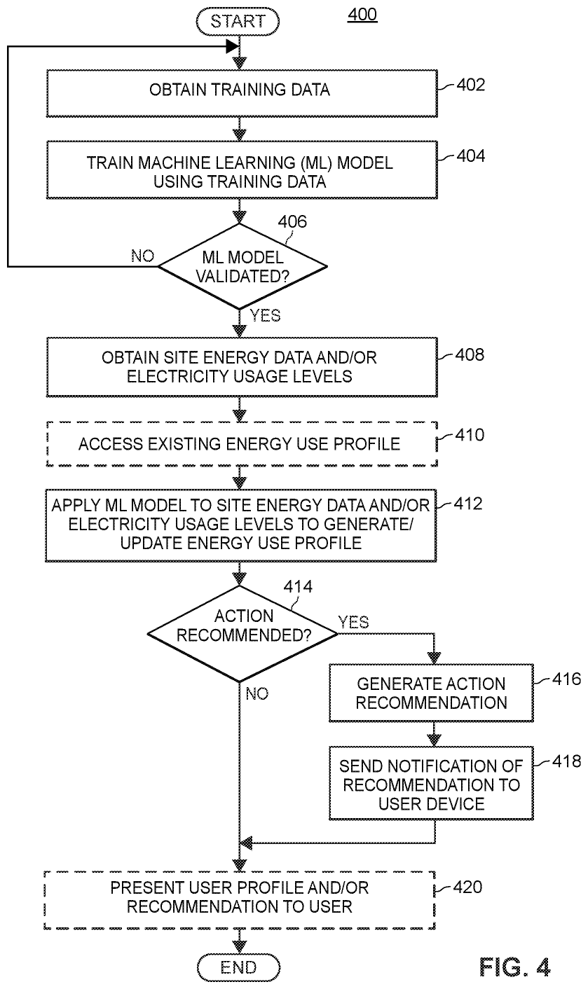

The systems and components described herein may be configured to monitor and analyze energy use at a site 105, such as a structure 202. The computer-implemented methods described below with respect to FIGS. 3 and 4 may be implemented separately or together to measure real-time electricity characteristics (e.g., variations in instantaneous voltage levels measured by the EM device 170), analyze such site energy data to determine electricity usage levels for the structure 202 or portions thereof, and generate or update an energy use profile associated with the structure 202. By so monitoring and analyzing the electricity characteristics in an electrical circuit via a plug-in EM device 170, information regarding energy use at the site 105 may be obtained without needing to install a monitoring device in a supply line to or within a distribution board 208, thereby enabling more flexible and convenient measurement of energy usage.

FIG. 3 illustrates an exemplary energy use monitoring method 300 for detecting energy usage at a site and generating or updating an energy use profile associated with the site. The energy use monitoring method 300 may be implemented by one or more components of the system 100, either separately or in communication. Processing or communication aspects of the method 300 may be implemented by processors or controllers of various components of the system 100. For example, the EM device 170 may be configured to perform the measurement, processing, storage, communication, and/or presentation aspects of method 300. In another example, the EM device 170 may directly or indirectly provide data measured at an outlet 212j (or data derived therefrom) to another device for further processing and use (e.g., smart home controller 120 or server 140). In various embodiments, the method 300 may be modified to include additional, fewer, or alternative aspects.

The energy use monitoring method 300 may begin with plugging an EM device 170 into an outlet 212j of an electrical circuit at a site 105 (block 302), at which point the EM device 170 may in some embodiments attempt to communicate with one or more smart appliances and/or smart meters at the site 105 (block 304). The EM device 170 then monitors a circuit voltage or other real-time electricity characteristics at the outlet 212j (block 306). In some embodiments, the EM device 170 may transmit site energy data to the server 140 for analysis (block 308). Whether analyzed by the EM device 170 or the server 140, the site energy data is analyzed by one or more processors to determine electricity usage levels for the site 105 (block 310). The one or more processors then determine whether to generate or update an energy use profile (block 312). If no energy use profile is to be generated or update, the EM device 170 continues monitoring the electrical circuit at block 306 or attempting to establish communication connections with smart appliances and/or smart meters at block 304. If an energy use profile is to be generated or updated, the one or more processors generate or update the energy use profile based upon the electricity usage levels determined form the site energy data (block 314). In some embodiments, the energy use profile may be presented to a user 130 (block 316), such a by a user device 135. If it is determined to continue monitoring (block 318), the EM device 170 continues monitoring the electrical circuit at block 306 or attempting to establish communication connections with smart appliances and/or smart meters at block 304. Otherwise, the method 300 may end.

At block 302, the EM device 170 may be plugged into the outlet 212j connected to an electrical circuit within a structure 202 at a site 105. The outlet 212j may be selected as an outlet in proximity to the electrical distribution board 208 in order to better monitor voltages or other real-time electricity characteristics associated with energy usage levels. The EM device 170 may be configured to be associated with a user 130 or user account associated with the site 105, either before or after being plugged into the outlet 212j. In some embodiments, a plurality of EM devices 170 may be plugged into a plurality of outlets at the site 105 in order to better monitor energy use.

At block 304, in some embodiments, the EM device 170 may attempt to establish communication connections with any smart appliances (e.g., a smart stove 110b or a smart washing machine 110c) or smart meters (e.g., smart meter 110a) at the site 105. In some embodiments, such attempts to communicate electronically with such smart devices 110 may be performed initially when the EM device 170 is plugged in, as well as periodically during monitoring. The communication connections may be established by wireless communication between the EM device 170 and any smart devices 110 within communication range via any wireless communication protocols. By establishing one or more communication connections with smart devices 110, the EM device 170 may obtain operating data regarding operation of the one or more smart electrical appliances 110b or 110c or metered energy usage data regarding total electricity usage levels of one or more circuits at the structure 202 from the smart meter 110a. In some embodiments, the operating data of the smart appliances may include one or more appliance usage levels associated with the respective smart appliances 110b or 110c, which may be one or more of the following: a furnace, a water heater, a dishwasher, an oven, a washer, a dryer, or an electric vehicle charger. In further embodiments, communication connections may be established between the smart devices 110 and an analytics server (e.g., server 140 or a server implemented by the smart home controller 120), rather than through the EM device 170. In still further embodiments, the EM device 170 may attempt to obtain communication signals from smart devices 110 without establishing a communication connection, such as by detecting signals broadcast by the smart devices 110 (e.g., undirected periodic broadcast signals).

At block 306, the EM device 170 monitors the circuit voltage at the outlet 212j to collect site energy data regarding real-time electricity characteristics of the electrical circuit to which the EM device 170 is connected. Such site energy data may be measured or otherwise collected by the EM device 170 on an ongoing basis through one or more time intervals. In some embodiments, additional or alternative real-time electricity characteristics may be monitored by the EM device 170, such as current through the EM device 170. In further embodiments, the EM device 170 may monitor the voltage to detect variations in the instantaneous voltage levels as the real-time electricity characteristics of the electrical circuit. Such variations may be particularly useful in determining electricity usage levels because variations in power drawn by the electrical components at the site 105 cause changes in the voltage profile in the circuit due to the introduction of additional load on the circuit or connected circuits. The real-time electricity characteristics monitored by the EM device 170 may be combined by the EM device 170 or other components with other data obtained from the smart devices 110 to generate site energy data.

At block 308, in some embodiments, the EM device 170 may transmit site energy data based upon the monitored or derived real-time electricity characteristics to an analytics server (e.g., server 140 or a server implemented by the smart home controller 120). Such site energy data may include the real-time electricity characteristics generated by EM device 170, operating data from smart appliances 110b-c, and/or metered energy usage data from a smart meter 110a. In some embodiments, the site energy data may be transmitted from the EM device 170 to the server 140 directly through network 125 or indirectly through the smart home controller 120 and the network 125. In further embodiments, the EM device 170 may transmit the real-time electricity characteristics to the server 140, while the smart home controller 120 may transmit any operating data or metered energy usage data to the server 140. The site energy data may be transmitted in one or more electronic messages for each time interval monitored, either periodically or upon occurrence of a triggering event (e.g., in response to a data request from the server 140). To facilitate transmission of the site energy data via one or more messages, the server 140 may establish a communication connection with the EM device 170 or the smart home controller 120.

At block 310, the one or more processors of the EM device 170 or analytics server (e.g., server 140) may determine electricity usage levels based upon the site data (i.e., the real-time electricity characteristics of the electrical circuit and/or operating data from smart devices 110). The electricity usage levels may be determined for a plurality of times within a time interval based upon a corresponding plurality of values of the real-time electricity characteristics at such times. Moreover, the electricity usage levels may include a total electricity usage level for the structure 202 and/or specific electricity usage levels for individual electrical devices 212a-g within the structure 202. For example, the electricity usage levels may include one or more appliance usage levels associated with respective one or more electrical appliances, including: a furnace, a water heater, a dishwasher, an oven, a washer, a dryer, or an electric vehicle charger. In some embodiments, determining the appliance usage levels may include identifying the individual electrical appliances based upon the real-time electricity characteristics, such as by applying a trained machine learning model to detect the electrical appliances from unique electrical signatures of the appliances. Thus, in some embodiments, determining the electricity usage levels may comprise applying a trained machine learning model to the real-time electricity characteristics for a time interval to determine energy usage by a plurality of distinct electrical loads at the structure (e.g., electrical appliances or other electrical devices 212a-g). More generally, a trained machine learning model may be applied to the site data to determine the electricity usage levels for the structure 202. In some embodiments, the electricity usage levels may be determined based in part upon the operating data received from one or more smart appliances 110b-c or metered energy usage data received from a smart meter 110a.

At block 312, the one or more processors determine whether to generate or update an energy use profile for the site 105 based upon the determined electricity usage levels. In some embodiments, generating or updating the energy use profile may be triggered by availability of sufficient site data for initial generation of the profile or sufficient site data to update an existing profile or by passage of a sufficient time interval since the profile was last generated or updated. If it is determined not to generate or update an energy use profile, the method 300 proceeds to continue monitoring the circuit at block 306 and, in some embodiments, attempting to establish communication connections with smart devices 110 at block 304. If it is determined to generate or update an energy use profile, the method 300 proceeds to generate or update such profile at block 314.

At block 314, the one or more processors generate or update the energy use profile for the site 105 based upon the electricity usage levels. The energy use profile may include one or more indications of energy usage levels for the structure 202, such as energy use scores for the structure or individual electrical devices 212a-g within the structure 202. In some embodiments, the scores or other indications of energy usage levels may include both current energy use data for a recent time interval and historical energy use data for one or more previous time intervals.

Thus, the energy use profile may contain data indicative of trends or changes in energy use over time. In some embodiments, the energy use profile may include recommendations for actions to improve energy use (e.g., by reducing energy use, increasing the efficiency of electrical appliances, or shifting the time of energy use). The energy use profile may include indications of overall energy usage, in addition to or alternatively to indications of specific energy usage (e.g., by time of day, by electrical circuit, or by specific appliances). The recommendations, energy use profile, and related or associated data and information may be presented to the user or homeowner in various manners, such as visually, graphically, or textually on a display or screen, such as via a mobile device, or verbally or audibly, such as via a voice bot, chatbot, or ChatGPT bot.

The energy use profile may include data pertaining to the structure 202 as a whole. For example, the energy use profile may include data reflecting a total electricity or average usage rate over a period of time. As another example, the energy use profile may include time-of-day, day-of-week, etc., data reflecting times at which the structure 202 as a whole uses more or less electricity. Further, the energy use profile may detail specific types, classes, or specifications of electrical devices 212a-g that behave differently or consume a different amount of electricity compared to other electrical devices within the structure 202.

In some embodiments, the energy use data of the energy use profile may include data relating to energy use by specific electrical devices 212a-g at the site 105. Such device-specific data may include information regarding one or more appliances, which may be smart appliances 110b-c. In some embodiments, the energy use data may include an inventory of one or more electrical appliances generated by identifying respective energy use signatures in the real-time electricity characteristics identifying the appliances, such as non-communicating appliances. In further embodiments, the energy use data may include indications of conditions of one or more electrical appliances relating to operating efficiency of such appliances, which may be generated from the real-time electricity characteristics or from operating data received from smart appliances 110b-c. Such condition indications may include efficiency or performance scores indicating whether or to what degree the smart or non-communicating appliances are operating efficiency or within modern quality parameters. For example, aging appliances may receive low scores based upon inefficient energy usage relative to modern standards, or such appliances may receive low scores based upon degraded performance relative to past performance or to performance of other appliances of similar design and age. In still further embodiments, the energy use data may include one or more recommendations regarding adjustments to usage of one or more electrical appliances based upon the condition indications or appliance-specific electricity usage levels.

At block 316, in some embodiments, the one or more processors may cause the energy use profile to be presented to a user 130, such as by presentation at a user device 135. Causing the energy use profile (including any recommended actions) to the user 130 may include generating and sending an electronic communication to the user device 135 or the smart home controller 120 for presentation to the user 130. This may include sending the electronic message to an energy use monitoring application running on the user device 135 or smart home controller 120. Upon receipt of the electronic message, the user device 135 or smart home controller 120 may present the contents of the message to the user 130. In some embodiments, a summary may first be presented, with additional energy use data being available upon user interaction. In certain embodiments, the electronic messages generated, recommendations, energy use profile, and related information may be presented to the user or homeowner in various manners, such as visually, graphically, or textually on a display or screen, such as via a mobile device or smart home controller display or individual smart appliance displays, or verbally or audibly, such as via a voice bot, chatbot, ChatGPT bot, or other bot, such as a bot associated with a smart home, smart home controller, or individual smart appliance.

At block 318, the one or more processors determine whether to continue monitoring energy use at the site 105. In some embodiments, monitoring may continue until the EM device 170 is unplugged from the outlet 212j. If it is determined to continue monitoring energy use, the method 300 proceeds to continue monitoring the circuit at block 306 and, in some embodiments, attempting to establish communication connections with smart devices 110 at block 304. If it is determined to discontinue energy use monitoring, the method may 300 end.

FIG. 4 illustrates an exemplary energy use analysis method 400 that may be implemented by one or more processors to analyze electrical energy use at a site 105 using machine learning (ML) techniques. The method 400 may be implemented by one or more components of the system 100, either separately or in communication. Processing or communication aspects of the method 400 may be implemented by processors or controllers of various components of the system 100. For example, the server 140 may be configured to obtain site energy data and/or electricity usage levels generated by the EM device 170 based upon data measured at an outlet 212j (or data derived therefrom), which may then be further analyzed by the server 140. Training the ML model may be performed by the server 140 or by another one or more servers, then stored for later use at various times for various sites. In various embodiments, the method 400 may be modified to include additional, fewer, or alternative aspects.

The energy use analysis method 400 may begin with training an ML model by obtaining training data (block 402), training the ML model on the training data (block 404), and attempting to validate the ML model using validation data (block 406). The training process may continue at block 402-406 until the ML model is validated. After validation of the ML model, the process continues with one or more processors obtaining site energy data or electricity usage levels for a monitored site 105 (block 408) and, in some embodiments, accessing an existing energy use profile for the site 105 (block 410). The trained ML model is then applied to the site energy data or electricity usage levels to generate or update an energy use profile for the site 105 (block 412). The one or more processors then determine whether an action is recommended based upon the energy use profile (block 414). If an action is recommended, the one or more processors generate an action recommendation (block 416) and send a notification of the recommendation to a user device 135 (block 418). When the user device 135 receives the notification or if no action is recommended, in some embodiments, the energy use profile may be presented to a user 130 of the user device 135 (block 420). The method 400 then ends.

At block 402, one or more processors (e.g., processors of controller 142 of server 140) may obtain training data from which to train an ML model for use in generating energy use data within an energy use profile. In some embodiments, the training data may be obtained from a database 146 storing energy use data associated with site energy data and electricity usage levels at a plurality of times for a plurality of sites. In further embodiments, the training data may include voltage or other electricity characteristics associated with individually identifiable loads (e.g., electrical appliances) in order to train the ML model to identify such electrical devices or conditions of such electrical devices. For example, the training data may further include indications of operating status, condition, or efficiency of the individually identifiable devices, thereby facilitating training the ML model to detect such information about electrical devices based upon detected patterns in the instantaneous voltage levels or other real-time electricity characteristics measured by an EM device 170. In still further embodiments, part or all of the training data may be obtained from a database 146 storing historical energy use data for the specific structure 202 at the site 105 to be analyzed. Thus, the ML model may be trained based upon the past site energy data and/or electricity usage levels indicating energy use at the site 105 in order to generate a trained ML model specific to the site 105. Such historical energy use data for the site 105 may be obtained for a plurality of time intervals covering a sufficient duration to establish a baseline energy use profile (e.g., over the course of months or years). In some embodiments, the training data may be a combination of historical energy use data from the site 105 and energy use data from other sites, thereby enabling the ML model to be trained in a robust manner, while also being customized to the specific site 105. Obtaining the training data may further include preprocessing the training data to ensure data integrity and sufficiency for training the ML model.

At block 404, the one or more processors may train the ML model using at least a portion of the training data. Training may continue until a threshold is reached, such as a predetermined or variable number of training iterations, time interval, or until changes to model parameters are below a threshold. The ML model may be trained using a supervised or unsupervised machine-learning program or algorithm to determine or predicts aspects of energy use (e.g., electricity usage levels, individual appliance energy use or operating condition, energy use scores, or recommendations) based upon input data collected by an EM device 170 (e.g., voltage levels, smart appliance operating data, or electricity usage levels). The machine-learning program or algorithm may employ a neural network, which may be a convolutional neural network, a deep learning neural network, or a combined learning module or program that learns in two or more features or feature datasets in a particular areas of interest. In one embodiment, a generative adversarial neural network may be used. The machine-learning programs or algorithms may also include natural language processing, semantic analysis, automatic reasoning, regression analysis, support vector machine (SVM) analysis, decision tree analysis, random forest analysis, K-Nearest neighbor analysis, naïve Bayes analysis, clustering, reinforcement learning, or other machine-learning algorithms or techniques. Training the ML model may involve identifying and recognizing patterns in existing data in order to facilitate making predictions for subsequent data. In some embodiments, due to the processing power requirements of training ML models, the selected model may be trained using additional computing resources (e.g., cloud computing resources) based upon data provided by the server 140. In some embodiments, the ML model may be partially trained using energy use data from other sites, then further trained for the specific site 105 using historical energy use data for the site 105. Thus, the ML model may initially be a partially or fully trained ML model, which may then be further trained using historical energy use data specific to the site 105.

At block 406, the one or more processors may attempt to validate the trained ML model using validation data, which may be separately obtained data or may be an additional portion of the training data not used to train the ML model. Validating the ML model may include comparing the output of the trained ML model when applied to the validation data against the actual values of the corresponding variables in the validation data for a plurality of sites. The ML model may be determined to be validated when the error level of the ML model predictions relative to the actual validation data values are within acceptable threshold limits, which limits may be static or variable based upon the time spent training the ML model. However validated, the trained ML model may be stored for later use upon a determination of validation, and the method 400 may proceed to block 408. If the trained ML model is not validated by the one or more processors, the ML model may be retrained by selecting or obtaining a new set of training data and retraining the ML model on the new set of training data at blocks 402 and 404.

At block 408, one or more processors may obtain site energy data or electricity usage levels associated with a specific site 105. The one or more processors may be the same processors used to train and validate the ML model, or they may be different processors (e.g., processors of another server 140, of the EM device 170, or of a smart home controller 120). The site energy data or electricity usage levels may be obtained as discussed above with respect to energy use monitoring method 300. In some embodiments, the site energy data or electricity usage levels may be obtained by a server 140 from the smart home controller 120 or the EM device 170 via network 125. In some embodiments, the site energy data or electricity usage levels may be retrieved from memory (e.g., a database 146 of server 140) on a periodic or episodic basis for analysis.

At block 410, in some embodiments, the one or more processors may access an existing energy use profile for the site 105. Accessing the existing energy use profile may include retrieving energy use data associated with the profile from a database 146, which energy use data may be used in updating the energy use profile for the site 105. In some embodiments, the existing energy use profile may include historical energy use data indicating averages, ranges, trends, or other historical energy use information for the site 105. Such historical energy use data may be used in determining whether action recommendations are needed or in generating action recommendations, as discussed below.

At block 412, the one or more processors may apply the trained ML model to the site energy data or electricity use levels to generate or update an energy use profile. Generating the energy use profile may include generating energy use data for one or more time intervals based upon site energy data or electricity usage levels derived therefrom. Updating the energy use profile may similarly include generating energy use data for a current time interval, which may be added to historical energy use data from past intervals or may be used to adjust such historical energy use data.

In some embodiments, the ML model may be applied to the site energy data to determine electricity usage levels from which the energy use profile may be generated or updated. Generating or updating the energy use profile may include using the electricity usage levels as energy use data within the energy use profile or deriving energy use data from the electricity usage levels. For example, the trained ML model may be applied to real-time electricity characteristics (e.g., voltages or variations in voltages) for a time interval to determine a plurality of electricity usage levels for the structure 202, some of which may indicate energy usage by each of one or more distinct electrical loads at the structure 202 (e.g., electrical devices 212a-g). In some such embodiments, an additional ML model may be applied to the electricity usage levels (and, in some instances, historical energy use data from an existing energy use profile) to generate or update the energy use profile.

In further embodiments, the ML model may be applied to the electricity use levels to generate or update energy use data for the energy use profile. For example, the trained ML model may be applied to the electricity usage levels for a time interval to determine one or more energy use scores for the structure 202, such as a total energy use score or appliance-specific energy use scores indicating energy usage by each of one or more distinct electrical loads at the structure 202 (e.g., electrical devices 212a-g).

In still further embodiments, the ML model may be applied to both the site energy data and the electricity use levels to generate or update energy use data for the energy use profile. For example, site data relating to operating data of smart devices 110 may be analyzed together with energy usage levels to generate current energy use data relating to total energy use or appliance-related energy use for the energy use profile.

At block 414, the one or more processors may determine an action should be recommended to a user 130 based upon the energy use data within the energy use profile. In some embodiments, such a recommendation may be determined to be needed based upon the current energy use data, without reference to historical energy use data, such as by determining a high level of energy use by an identifiable electrical device 212a-g or by comparing one or more energy use scores against reference levels for similar structures (e.g., homes or offices of similar size and location). In further embodiments, such a recommendation may be determined to be needed based upon a comparison of current energy use data against historical energy use data for the structure 202. If it is determined that an action should be recommended, the method 400 proceeds to generate such a recommendation and send a corresponding notification to a user device 135 at block 416 and 418. If it is determined no action should be recommended, the method 400 proceeds to present the user profile at the user device 135 at block 420 in some embodiments or ends.

In some embodiments in which an existing energy use profile has been accessed, the current energy use data may be determined for a current time interval based upon one or more electricity usage levels at the structure 202 based upon real-time electricity characteristics detected by the EM device 170 at a plurality of times within the current time interval. Such current energy use data may be compared against corresponding historical energy use data from one or more past intervals, which historical energy use data may similarly be determined for the one or more past intervals based upon one or more electricity usage levels at the structure 202 based upon real-time electricity characteristics detected by the EM device 170 at a plurality of times within each such past time interval. The one or more processors may thus determine whether a recommendation is needed based upon the comparison of current energy use data against the corresponding historical energy use data for the structure 202, such as by determining a recommendation is needed when the difference between current and historical energy use data exceeds a threshold.

At block 416, the one or more processors may generate one or more action recommendations based upon the energy use profile, the action recommendation indicating an action relating to energy usage to be taken by a user 130. Such recommendations may involve changes to the use levels or timing of use of electrical devices 212a-g or other changes that may be made to reduce or improve energy usage. For example, the recommendations may include recommended adjustments to usage of one or more electrical appliances based upon corresponding usage levels determined from the site energy data or electricity usage levels. As another example, the recommendations may include an indication of a need for service, repair, or replacement of an electrical device (e.g., a malfunctioning or inefficient appliance) based upon corresponding usage levels determined from the site energy data or electricity usage levels. Such a recommendation may be based upon identifying a change between an energy use level or score associated with such electrical device at a first time interval and a corresponding energy use level or score at a second time interval. In some embodiments, an action recommendation may be generated to alert a user 130 of a potentially hazardous condition associated with one or more electrical devices (e.g., excessive energy use by a sump pump indicating potential for failure or flooding).

At block 418, the one or more processors may send a notification of the action recommendation to a user 130, such as via a user device 135. The notification may include information regarding the basis of the recommendation (e.g., electricity usage levels or energy use scores), as well as an indication of the recommendation. In some embodiments, the notification may be sent together with or as part of an energy use profile. Sending the notification may include generating and sending an electronic message from the one or more processors (e.g., from the server 140) to the user device 135 or smart home controller 120 for presentation to the user 130.

At block 420, in some embodiments, the one or more processors may cause the energy use profile and, if applicable, the notification of the action recommendation to be presented to the user 130, such as via a user device 135. Causing the energy use profile and/or the notification of recommendation action to the user 130 may include generating and sending an electronic communication to the user device 135 or the smart home controller 120 for presentation to the user 130. This may include sending the electronic message to an energy use monitoring application running on the user device 135 or smart home controller 120. Upon receipt of the electronic message, the user device 135 or smart home controller 120 may present the contents of the message to the user 130. The method 400 may then end.

### Exemplary Analytics Server

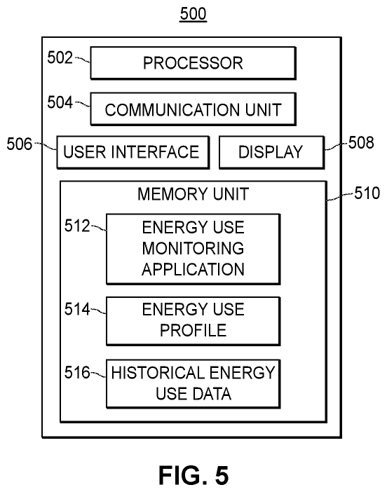

FIG. 5 illustrates a block diagram of an exemplary analytics server 500 for analyzing electricity usage in accordance with certain aspects of the present disclosure. Such analytics server 500 may be implemented by one or more components of the system 100, such as the server 140 or the smart home controller 120. In some embodiments, the EM device 170 may implement the analytics server 500 in addition to monitoring functionality described elsewhere herein. Although one analytics server 500 is illustrated, some embodiments may include multiple analytics servers 500. As illustrated, the analytics server 500 may include a processor 502, a communication unit 504, a user interface 506, a display 508, and a memory unit 510. In further embodiments, the analytics server 500 may include additional, fewer, or alternate components, including those discussed elsewhere herein.

Processor 502 may be implemented as any suitable type and/or number of processors, such as a host processor for the relevant device in which analytics server 500 is implemented, for example. Processor 502 may be configured to communicate with one or more of communication unit 504, user interface 506, display 508, and/or memory unit 510 to send data to and/or to receive data from one or more of these components.

For example, processor 502 may be configured to communicate with memory unit 510 to store data to and/or to read data from memory unit 510. In accordance with various aspects, memory unit 510 may be a computer-readable non-transitory storage device, and may include any combination of volatile (e.g., a random access memory (RAM)), or a non-volatile memory (e.g., battery-backed RAM, FLASH, etc.). In one embodiment, memory unit 510 may be configured to store instructions executable by processor 502. These instructions may include machine readable instructions that, when executed by processor 502, cause processor 502 to perform various processes.

Communication unit 504 may be configured to facilitate data communications between analytics server 500 and one or more components of local or external networks (e.g., local networks 115 or networks 125). Communication unit 504 may be configured to facilitate communications between one or more networks or network components in accordance with any suitable number or type of communication protocols, which may be the same communication protocols as one another or different communication protocols based upon the particular network component or network.

The communication unit 504 may be implemented with any suitable combination of hardware and software to facilitate this functionality. For example, communication unit 504 may be implemented with any suitable number of wired and/or wireless transceivers, network interfaces, physical layers, ports, etc. Communication unit 504 may send and receive data in accordance with one or more applications (e.g., web-based applications) hosted on analytics server 500, which may facilitate data communications between analytics server 500 and one or more devices (e.g., EM device 170).

Furthermore, communication unit 504 may be configured to receive data from one or more devices (e.g., user device 135), such as user selections and requests for information. The data received from other computing devices or network components may then be stored in any suitable portion of memory unit 510, for example. This data may be accessible and available to the various software applications stored on memory unit 510 and executed by processor 502 such that the various functions of the embodiments as described herein may be carried out as needed.

User interface 506 may be configured to allow a user to interact with analytics server 500. For example, user interface 506 may include a user-input device, such as an interactive portion of display 508 (e.g., a “soft” keyboard displayed on display 508), an external hardware keyboard configured to communicate with analytics server 500 via a wired or a wireless connection, one or more keyboards, keypads, an external mouse, or any other suitable user-input device.

Display 508 may be implemented as any suitable type of display and may facilitate user interaction with analytics server 500 in conjunction with user interface 506. For example, display 508 may be implemented as a capacitive touch screen display, a resistive touch screen display, etc. In various embodiments, display 508 may be configured to work in conjunction with processor 502 or user interface 506 to display various prompts, selections, etc.

The memory unit 510 may store various applications, modules, routines, and/or data that may be used in implementing the various methods and processes disclosed herein. For example, the memory unit 510 may store computer-readable instructions for implementing an energy use monitoring application 512 configured to obtain and analyze site energy data, as described elsewhere herein. The memory unit 510 may further store one or more energy use profiles 514, which may be generated by or accessed by the energy use monitoring application 512. Similarly, the memory unit 510 may store historical energy use data 516 associated with one or more sites 105, which may be used by the energy use monitoring application 512 to determine energy usage levels or trends or to detect changes in energy usage levels that may indicate action is required.

### Additional Considerations

Although the preceding text sets forth a detailed description of numerous different embodiments, it should be understood that the legal scope of the invention is defined by the words of the claims set forth at the end of this patent. The detailed description is to be construed as exemplary only and does not describe every possible embodiment, as describing every possible embodiment would be impractical, if not impossible. One could implement numerous alternate embodiments, using either current technology or technology developed after the filing date of this patent, which would still fall within the scope of the claims.

It should also be understood that, unless a term is expressly defined in this patent using the sentence “As used herein, the term ‘______’ is hereby defined to mean . . . ” or a similar sentence, there is no intent to limit the meaning of that term, either expressly or by implication, beyond its plain or ordinary meaning, and such term should not be interpreted to be limited in scope based upon any statement made in any section of this patent (other than the language of the claims). To the extent that any term recited in the claims at the end of this patent is referred to in this patent in a manner consistent with a single meaning, that is done for sake of clarity only so as to not confuse the reader, and it is not intended that such claim term be limited, by implication or otherwise, to that single meaning.

With the foregoing, a customer may opt in to a program to receive a reward, insurance discount, or other type of benefit. In some aspects, customers may opt in to a rewards, loyalty, or other program associated with use of the well-being application, such as a rewards program that collects data and provides incentives for performing well-being tasks. The customers may therefore allow a remote server to collect sensor, telematics, biometric, mobile device, and other types of data discussed herein. With customer permission or affirmative consent, the data collected may be analyzed to provide certain benefits to customers. For instance, insurance cost savings may be provided to customers based upon reducing their risk through improving their well-being. Recommendations that lower risk or provide cost savings to customers may also be generated and provided to customers based upon data analysis. Other functionality or benefits of the systems and methods discussed herein may also be provided to customers in return for them allowing collection and analysis of the types of data discussed herein. In return for providing access to data, risk-averse insured customers may receive discounts or insurance cost savings on home, renters, vehicle, personal articles, life, health, auto, and other types of insurance from the insurance provider.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Additionally, certain embodiments are described herein as including logic or a number of routines, subroutines, applications, or instructions. These may constitute either software (code embodied on a non-transitory, tangible machine-readable medium) or hardware. In hardware, the routines, etc., are tangible units capable of performing certain operations and may be configured or arranged in a certain manner. In example embodiments, one or more computer systems (e.g., a standalone, client or server computer system) or one or more modules of a computer system (e.g., a processor or a group of processors) may be configured by software (e.g., an application or application portion) as a module that operates to perform certain operations as described herein.

In various embodiments, a module may be implemented mechanically or electronically. For example, a module may comprise dedicated circuitry or logic that is permanently configured (e.g., as a special-purpose processor, such as a field programmable gate array (FPGA) or an application-specific integrated circuit (ASIC) to perform certain operations. A module may also comprise programmable logic or circuitry (e.g., as encompassed within a general-purpose processor or other programmable processor) that is temporarily configured by software to perform certain operations. It will be appreciated that the decision to implement a module mechanically, in dedicated and permanently configured circuitry, or in temporarily configured circuitry (e.g., configured by software) may be driven by cost and time considerations.

Accordingly, the term “module” should be understood to encompass a tangible entity, be that an entity that is physically constructed, permanently configured (e.g., hardwired), or temporarily configured (e.g., programmed) to operate in a certain manner or to perform certain operations described herein. Considering embodiments in which modules are temporarily configured (e.g., programmed), each of the modules need not be configured or instantiated at any one instance in time. For example, where the modules comprise a general-purpose processor configured using software, the general-purpose processor may be configured as respective different modules at different times. Software may accordingly configure a processor, for example, to constitute a particular module at one instance of time and to constitute a different module at a different instance of time.

Modules can provide information to, and receive information from, other modules. Accordingly, the described modules may be regarded as being communicatively coupled. Where multiple such modules exist contemporaneously, communications may be achieved through signal transmission (e.g., over appropriate circuits and buses) that connect the modules. In embodiments in which multiple modules are configured or instantiated at different times, communications between such modules may be achieved, for example, through the storage and retrieval of information in memory structures to which the multiple modules have access. For example, one module may perform an operation and store the output of that operation in a memory device to which it is communicatively coupled. A further module may then, at a later time, access the memory device to retrieve and process the stored output. Modules may also initiate communications with input or output devices, and may operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods or routines described herein may be at least partially processor-implemented. For example, at least some of the operations of a method may be performed by one or more processors or processor-implemented modules. The performance of certain of the operations may be distributed among the one or more processors, not only residing within a single machine, but deployed across a number of machines. In some example embodiments, the one or more processors or processor-implemented modules may be located in a single geographic location (e.g., at a location of a mobile computing device or at a server farm). In other example embodiments, the one or more processors or processor-implemented modules may be distributed across a number of geographic locations.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information. Such memories may be or may include non-transitory, tangible computer-readable media configured to store computer-readable instructions that may be executed by one or more processors of one or more computer systems.

As used herein any reference to “one embodiment” or “an embodiment” means that a particular element, feature, structure, or characteristic described in connection with the embodiment is included in at least one embodiment. The appearances of the phrases “in one embodiment,” “in an embodiment,” “in some embodiments,” or similar phrases in various places in the specification are not necessarily all referring to the same embodiment or the same set of embodiments.

Some embodiments may be described using the terms “coupled,” “connected,” “communicatively connected,” or “communicatively coupled,” along with their derivatives. These terms may refer to a direct physical connection or to an indirect (physical or communicative) connection. For example, some embodiments may be described using the term “coupled” to indicate that two or more elements are in direct physical or electrical contact. The term “coupled,” however, may also mean that two or more elements are not in direct contact with each other, but yet still co-operate or interact with each other. Unless expressly stated or required by the context of their use, the embodiments are not limited to direct connection.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the description. This description, and the claims that follow, should be read to include one or at least one and the singular also includes the plural unless the context clearly indicates otherwise.

This detailed description is to be construed as exemplary only and does not describe every possible embodiment, as describing every possible embodiment would be impractical, if not impossible. One could implement numerous alternate embodiments, using either current technology or technology developed after the filing date of this application.

Upon reading this disclosure, those of skill in the art will appreciate still additional alternative structural and functional designs for the systems and methods disclosed herein. Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope defined in the appended claims.

The particular features, structures, or characteristics of any specific embodiment may be combined in any suitable manner and in any suitable combination with one or more other embodiments, including the use of selected features without corresponding use of other features. In addition, many modifications may be made to adapt a particular application, situation or material to the essential scope and spirit of the present invention. It is to be understood that other variations and modifications of the embodiments of the present invention described and illustrated herein are possible in light of the teachings herein and are to be considered part of the spirit and scope of the present invention.

Finally, the patent claims at the end of this patent application are not intended to be construed under 35 U.S.C. § 112 (f), unless traditional means-plus-function language is expressly recited, such as “means for” or “step for” language being explicitly recited in the claims. The systems and methods described herein are directed to an improvement to computer functionality, which may include improving the functioning of conventional computers in performing tasks.

What is claimed is:

1. A computer-implemented method for monitoring and analyzing electrical energy use of a structure, the method comprising:
monitoring, by an electricity monitoring device plugged into an outlet of an electrical circuit of the structure, real-time electricity characteristics of the electrical circuit during a time interval;
determining, by one or more processors, a plurality of electricity usage levels of the structure at a plurality of times within the time interval based upon the real-time electricity characteristics; and
generating, by the one or more processors, an energy use profile for the structure based upon the plurality of electricity usage levels, wherein the energy use profile includes one or more energy use scores for the structure.

2. The computer-implemented method of claim 1, wherein the real-time electricity characteristics comprise variations in instantaneous voltage levels.

3. The computer-implemented method of claim 1, wherein the plurality of electricity usage levels comprise one or more appliance usage levels associated with respective one or more electrical appliances, including one or more of the following: a furnace, a water heater, a dishwasher, an oven, a washer, a dryer, or an electric vehicle charger.

4. The computer-implemented method of claim 3, further comprising:
generating, by the one or more processors, one or more recommendations regarding adjustments to usage of the one or more electrical appliances based upon the one or more appliance usage levels.

5. The computer-implemented method of claim 3, further comprising:
obtaining, by the electricity monitoring device via wireless communication with the one or more electrical appliances, operating data regarding operation of the one or more electrical appliances, wherein the one or more electrical appliances are smart appliances, and
wherein the plurality of electricity usage levels are determined based in part upon the operating data.

6. The computer-implemented method of claim 3, further comprising:
generating, by the one or more processors, an inventory of the one or more electrical appliances by identifying respective energy use signatures in the real-time electricity characteristics.

7. The computer-implemented method of claim 6, wherein the energy use profile comprises one or more indications of conditions of the one or more electrical appliances relating to operating efficiency of the one or more electrical appliances.

8. The computer-implemented method of claim 1, further comprising:
obtaining, by the electricity monitoring device via wireless communication with a smart meter disposed at the structure, metered energy usage data regarding total electricity usage levels of one or more circuits at the structure, the one or more circuits including the electrical circuit, and
wherein the plurality of electricity usage levels are determined based in part upon the metered energy usage data.

9. The computer-implemented method of claim 1, wherein determining the plurality of electricity usage levels comprises applying a trained machine learning model to the real-time electricity characteristics for the time interval to determine energy usage by a plurality of distinct electrical loads at the structure.

10. The computer-implemented method of claim 1, wherein generating the energy use profile comprises applying a trained machine learning model to the plurality of electricity usage levels for the time interval to determine the one or more energy use scores,
further comprising:
monitoring, by the electricity monitoring device, additional real-time electricity characteristics of the electrical circuit during an additional time interval;
determining, by the one or more processors, an additional plurality of electricity usage levels of the structure at an additional plurality of times within the additional time interval;
generating, by the one or more processors, an updated energy use profile for the structure based upon the additional plurality of electricity usage levels by applying the trained machine learning model to the additional plurality of electricity usage levels for the additional time interval to generate one or more updated energy use scores;
determining, by the one or more processors, a change between at least one of the one or more energy use scores and a corresponding at least one of the one or more updated energy use scores exceeds a change threshold level; and
causing, by the one or more processors, a notification to be presented to a user of a user device indicating the change exceeding the change threshold level.

11. A computer system for monitoring and analyzing electrical energy use of a structure, comprising:
one or more processors;
a computer memory communicatively coupled to the one or more processors and storing executable instructions that, when executed by the one or more processors, cause the computer system to:
obtain, via an electricity monitoring device plugged into an outlet of an electrical circuit of the structure, real-time electricity characteristics of the electrical circuit during a time interval;
determine a plurality of electricity usage levels of the structure at a plurality of times within the time interval based upon the real-time electricity characteristics; and
generate an energy use profile for the structure based upon the plurality of electricity usage levels, wherein the energy use profile includes one or more energy use scores for the structure.

12. The computer system of claim 11, wherein obtaining the real-time electricity characteristics comprises:
establishing a communication connection with the electricity monitoring device; and
receiving the real-time electricity characteristics for the plurality of times within the time interval via the communication connection in one or more messages from the electricity monitoring device.

13. The computer system of claim 12, wherein the real-time electricity characteristics comprise variations in instantaneous voltage levels.

14. The computer system of claim 11, wherein:
the plurality of electricity usage levels comprise one or more appliance usage levels associated with respective one or more electrical appliances, including one or more of the following: a furnace, a water heater, a dishwasher, an oven, a washer, a dryer, or an electric vehicle charger;
the one or more electrical appliances are smart appliances configured for wireless communication;
the executable instructions further cause the computer system to obtain operating data regarding operation of the one or more electrical appliances from the one or more electrical appliances via the electricity monitoring device; and
the plurality of electricity usage levels are determined based in part upon the operating data.

15. The computer system of claim 11, wherein:
the plurality of electricity usage levels comprise one or more appliance usage levels associated with respective one or more electrical appliances, including one or more of the following: a furnace, a water heater, a dishwasher, an oven, a washer, a dryer, or an electric vehicle charger;
the executable instructions further cause the computer system to generate an inventory of the one or more electrical appliances by identifying respective energy use signatures in the real-time electricity characteristics; and
the energy use profile comprises one or more indications of conditions of the one or more electrical appliances relating to operating efficiency of the one or more electrical appliances.

16. A tangible, non-transitory computer-readable medium storing executable instructions for monitoring and analyzing electrical energy use of a structure that, when executed by one or more processors of a computer system, cause the computer system to:
obtain, via an electricity monitoring device plugged into an outlet of an electrical circuit of the structure, real-time electricity characteristics of the electrical circuit during a time interval;
determine a plurality of electricity usage levels of the structure at a plurality of times within the time interval based upon the real-time electricity characteristics; and
generate an energy use profile for the structure based upon the plurality of electricity usage levels, wherein the energy use profile includes one or more energy use scores for the structure.

17. The tangible, non-transitory computer-readable medium of claim 16, wherein the real-time electricity characteristics comprise variations in instantaneous voltage levels.

18. The tangible, non-transitory computer-readable medium of claim 16, wherein the plurality of electricity usage levels comprise one or more appliance usage levels associated with respective one or more electrical appliances, including one or more of the following: a furnace, a water heater, a dishwasher, an oven, a washer, a dryer, or an electric vehicle charger.

19. The tangible, non-transitory computer-readable medium of claim 18, wherein:
the one or more electrical appliances are smart appliances configured for wireless communication;
the executable instructions further cause the computer system to obtain operating data regarding operation of the one or more electrical appliances from the one or more electrical appliances via the electricity monitoring device; and
the plurality of electricity usage levels are determined based in part upon the operating data.

20. The tangible, non-transitory computer-readable medium of claim 18, wherein:
the executable instructions further cause the computer system to generate an inventory of the one or more electrical appliances by identifying respective energy use signatures in the real-time electricity characteristics; and
the energy use profile comprises one or more indications of conditions of the one or more electrical appliances relating to operating efficiency of the one or more electrical appliances.
